(19) United States
(12) Patent Application Publication
(10) Pub. No.: US 2019/0311886 A1
(43) Pub. Date: Oct. 10, 2019

(54) Microwave Plasma Source With Split Window

(71) Applicant: Applied Materials, Inc., Santa Clara, CA (US)

(72) Inventors: Siva Chandrasekar, Hosur (IN); Quoc Truong, San Ramon, CA (US); Dmitry A. Dzilno, Sunnyvale, CA (US); Avinash Shervegar, San Jose, CA (US); Jozef Kudela, Morgan Hill, CA (US); Tsutomu Tanaka, Santa Clara, CA (US); Alexander V. Garachtchenko, Mountain View, CA (US); Yanjun Xia, Newark, CA (US); Balamurugan Ramasamy, Bangalore (IN); Kartik Shah, Saratoga, CA (US)

(21) Appl. No.: 16/380,294

(22) Filed: Apr. 10, 2019

Related U.S. Application Data
(60) Provisional application No. 62/655,746, filed on Apr. 10, 2018.

(51) Int. Cl. H01J 37/32; C23C 16/511

(52) U.S. Cl. CPC H01J 37/32238; C23C 16/511

(57) ABSTRACT

Plasma source assemblies, gas distribution assemblies including the plasma source assembly and methods of generating plasma are described. The plasma source assemblies include a powered electrode with a ground electrode adjacent a first side, a first dielectric adjacent a second side of the powered electrode and at least one second dielectric adjacent the first dielectric on a side opposite the first dielectric. The sum of the thicknesses of the first dielectric and each of the second dielectrics is in the range of about 10 mm to about 17 mm.

### CROSS-REFERENCE TO RELATED APPLICATIONS

This application claims priority to U.S. Provisional Application No. 62/655,746, filed Apr. 10, 2018, the entire disclosure of which is hereby incorporated by reference herein.

### TECHNICAL FIELD

Embodiments of the disclosure generally relate to apparatus for plasma enhanced substrate processing. More particularly, embodiments of the disclosure relate to modular microwave plasma sources for use with processing chambers like spatial atomic layer deposition batch processors.

### BACKGROUND

Atomic Layer Deposition (ALD) and Plasma-Enhanced ALD (PEALD) are deposition techniques that offer control of film thickness and conformality in high-aspect ratio structures. Due to continuously decreasing device dimensions in the semiconductor industry, there is increasing interest and applications that use ALD/PEALD. In some cases, only PEALD can meet specifications for desired film thickness and conformality.

Semiconductor device formation is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

Typically, PEALD tools use capacitive plasma sources in RF/VHF frequency band up to several tens of MHz. These plasmas have moderate densities and can have relatively high ion energies. Using microwave fields at frequencies in GHz range instead, in certain resonant or wave-propagation electromagnetic modes, plasma of very high charge and radical densities and with very low ion energies can be generated. The plasma densities can be in the range of 10¹²/cm³ or above and ion energies can be as low as ˜5-10 eV. Such plasma features are becoming increasingly important in damage-free processing of modern silicon devices.

In a batch processing chamber, a microwave plasma assembly is exposed to a hot susceptor during wafer processing. Microwaves generated in the plasma assembly pass through a quartz window and generate plasma in the processing region above the susceptor. A significant amount of plasma power heats the quartz window to temperatures up to 1000° C., or more. Ultimately, the quartz window breaks because of higher stresses induced by large thermal gradients.

Therefore, there is a need in the art for improved apparatus and methods of forming microwave plasmas.

### SUMMARY

One or more embodiments of the disclosure are directed to plasma source assemblies comprising a housing with a top, bottom and at least one sidewall. A powered electrode is within the housing and has a first end and a second end defining a length. A ground electrode is on a first side of the powered electrode within the housing. The ground electrode is spaced from the powered electrode by a distance. A first dielectric is within the housing on a second side of the powered electrode. The first dielectric and ground electrode enclose the powered electrode. The first dielectric has an inner face adjacent the powered electrode and an outer face opposite the inner face. The inner face and outer face define a first thickness. At least one second dielectric is adjacent to the outer face of the first dielectric. Each of the second dielectrics has an inner face and an outer face defining a second thickness. The sum of the first thickness and the second thickness of each of the second dielectrics is in the range of about 10 mm to about 17 mm.

Additional embodiments of the disclosure are directed to methods of providing a plasma. Microwave power is provided from a microwave generator to a powered electrode enclosed in a dielectric with a ground electrode on a first side of the powered electrode, a first dielectric on a second side of the powered electrode and at least one second dielectric on an opposite side of the first dielectric from the powered electrode. The plasma is formed adjacent the second dielectric on a second side of the second dielectric opposite the first dielectric. The sum of the thickness of the first dielectric and the at least one second dielectric is in the range of about 10 mm to about 17 mm.

### BRIEF DESCRIPTION OF THE DRAWINGS

So that the manner in which the above recited features of embodiments of the disclosure can be understood in detail, a more particular description of embodiments of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a perspective view of a plasma source assembly in accordance with one or more embodiment of the disclosure;

FIG. 2 shows a cross-sectional view of the plasma source assembly of FIG. 1 taken along line 2-2′;

FIG. 3 shows an expanded view of region 3 of FIG. 2;

FIG. 4 shows an expanded view of region 4 of FIG. 3;

FIG. 5 shows a schematic view of a portion of a plasma source assembly in accordance with one or more embodiment of the disclosure;

FIG. 6A shows a cross-sectional schematic view of a partial plasma source assembly in accordance with one or more embodiment of the disclosure;

FIG. 6B shows an expanded view of region 6B of FIG. 6A;

FIG. 7 shows a cross-sectional schematic view of a partial plasma source assembly in accordance with one or more embodiment of the disclosure; and

FIG. 8 a schematic top view of a gas distribution assembly incorporating the plasma source assembly in accordance with one or more embodiments of the disclosure.

### DETAILED DESCRIPTION

Embodiments of the disclosure provide a substrate processing system for continuous substrate deposition to maximize throughput and improve processing efficiency. One or more embodiments of the disclosure are described with respect to a spatial atomic layer deposition chamber; however, the skilled artisan will recognize that this is merely one possible configuration and other processing chambers and plasma source modules can be used.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

As used in this specification and the appended claims, the terms “pie-shaped” and “wedge-shaped” are used interchangeably to describe a body that is a sector of a circle. For example, a wedge-shaped segment may be a fraction of a circle or disc-shaped structure and multiple wedge-shaped segments can be connected to form a circular body. The sector can be defined as a part of a circle enclosed by two radii of a circle and the intersecting arc. The inner edge of the pie-shaped segment can come to a point or can be truncated to a flat edge or rounded. In some embodiments, the sector can be defined as a portion of a ring or annulus.

Some embodiments of the disclosure are directed to microwave plasma sources. While the microwave plasma sources are described with respect to a spatial ALD processing chamber, those skilled in the art will understand that the modules are not limited to spatial ALD chambers and can be applicable to any injector situation where microwave plasma can be used. Some embodiments of the disclosure are directed to modular microwave plasma sources. As used in this specification and the appended claims, the term “modular” means that plasma source can be attached to or removed from a processing chamber. A modular source can generally be moved, removed or attached by a single person.

Some embodiments of the disclosure advantageously provide modular plasma source assemblies, i.e., a source that can be easily inserted into and removed from the processing system. For example, a gas distribution assembly made up of multiple injector units arranged to form a circular gas distribution assembly can be modified to remove one wedge-shaped gas injector unit and replace the injector unit with a modular plasma source assembly.

Some embodiments of the disclosure advantageously provide plasma source assemblies with a dielectric window that maintains vacuum when the window cracks or fails. Some embodiments advantageously provide plasma source assemblies with a decreased risk of chamber contamination upon window failure.

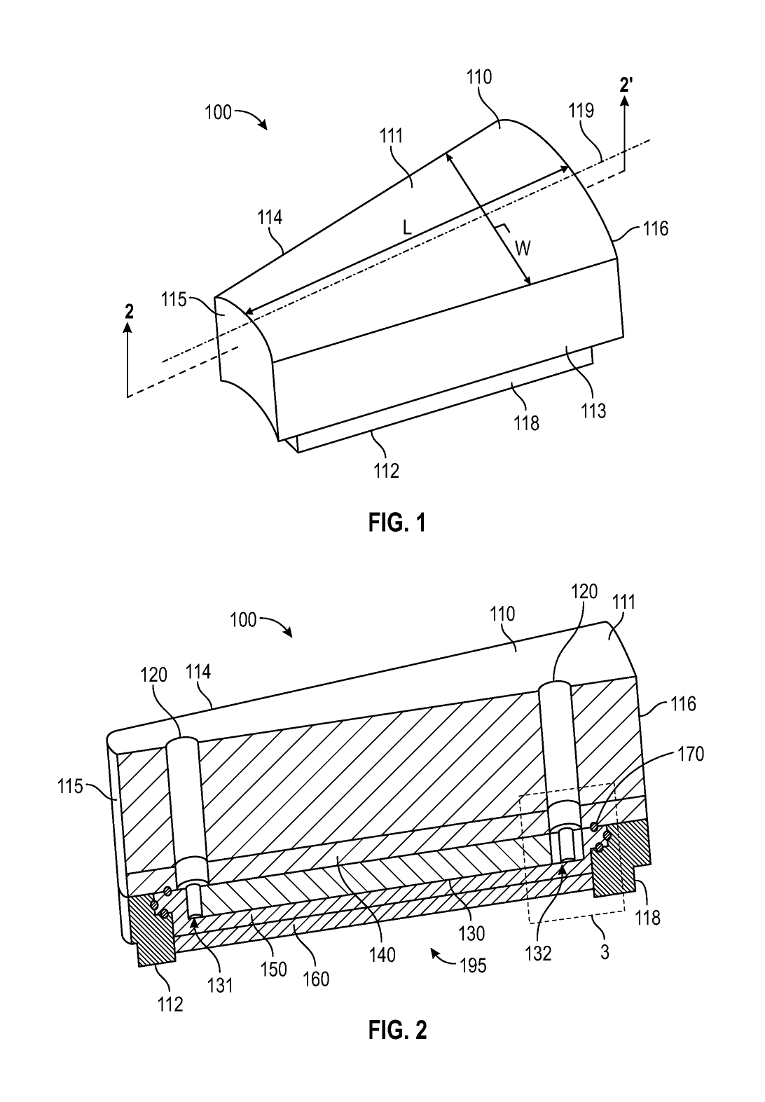

Referring to FIGS. 1 through 4, one or more embodiments of the disclosure are directed to plasma source assemblies 100 comprising a housing 110. The housing illustrated in FIG. 1 is a wedge-shaped component with a top 111, bottom 112, a first side 113, a second side 114, an inner peripheral end 115 and an outer peripheral end 116. The length L of the housing 110 is defined between the inner peripheral end 115 and the outer peripheral end 116 measured along the elongate central axis 119. The width W of the housing is defined as the distance between the sides 113, 114. The distance between the sides 113, 114 for width purposes can be measured normal to the elongate central axis 119. In the wedge-shaped housing 110 illustrated, the width increases from the inner peripheral end 115 to the outer peripheral end 116. The illustrated embodiment includes a ledge 118 which can be used to support the weight of the plasma source assembly 100 when inserted into a gas distribution assembly comprising a plurality of injector units including the plasma source assembly. For purposes of clarity, additional components/connections (e.g., power feed line, gas inlet) are omitted from FIGS. 2-4. However, the skilled artisan will recognize that these components can be connected to the housing 110 at any suitable location and are discussed further below.

FIG. 2 shows a cross-sectional view of the plasma source assembly 100 of FIG. 1 taken along line 2-2′. The housing 110 includes one or more passages 120 to allow a power connection (not shown) to pass through the housing 110. The power connection can be electrically connected to a powered electrode 130 within the housing 110. The powered electrode 130 has a first end 131 and a second end 132 defining a length.

A ground electrode 140 is on a first side of the powered electrode 130 within the housing 110. In FIG. 2, the ground electrode 140 is a portion of the housing 110 which is connected to electrical ground. The ground electrode 140 is spaced from the powered electrode by a distance. In the illustrated embodiment, the distance is defined as the thickness of the dielectric 150. The dielectric 150 is on a first side of the powered electrode 130. In some embodiments, the dielectric 150 is positioned above the powered electrode 130.

In the illustrated embodiment, a ground dielectric 135 is positioned between the powered electrode 130 and the ground electrode 140. The ground dielectric 135 can have any suitable thickness to space the powered electrode 130 from electrical ground. In some embodiments, the thickness of the ground electrode 140 varies from the inner peripheral end 115 to the outer peripheral end 116 of the housing 110.

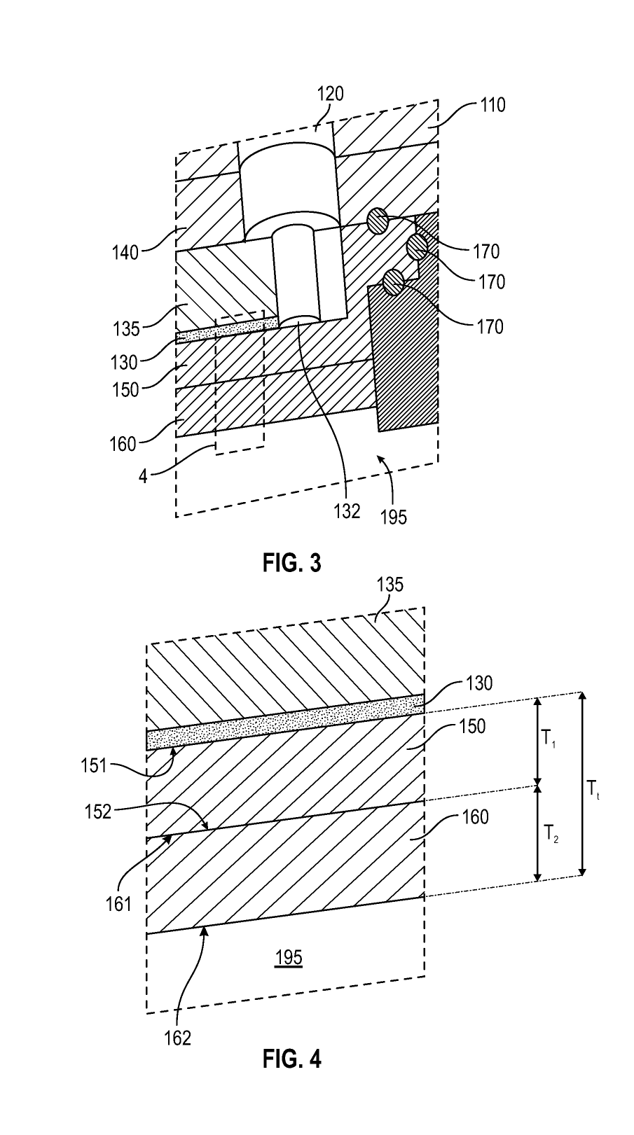

A first dielectric 150 is within the housing 110 on a second side of the powered electrode 130. The first dielectric 150 and ground electrode 140 enclose the powered electrode 130. The first dielectric 150 has an inner face 151 adjacent the powered electrode 130 and an outer face 152 opposite the inner face 151. The faces are illustrated in FIG. 4 which shows expanded region 4 of FIG. 3. The inner face 151 and outer face 152 of the first dielectric 150 define a first thickness T₁.

At least one second dielectric 160 is within the housing 110 adjacent to the outer face 152 of the first dielectric 150. Each of the second dielectrics 160 has an inner face 161 and an outer face 162. The inner face 161 and outer face 162 of the second dielectric 160 define a second thickness T₂.

Each of the ground dielectric 135, first dielectric 150 and at least one second dielectric 160 can be any suitable dielectric material. In some embodiments, each of the ground dielectric 135, first dielectric 150 and at least one second dielectric 160 are independently selected from the group consisting of quartz, ceramic and hybrid materials.

In some embodiments, each of the first dielectric 150 and the at least one second dielectric 160 are substantially planar. As used in this manner, the term “substantially planar” means that overall shape of the individual dielectric materials is planar. Some changes in the uniformity of the flatness are expected due to manufacturing variances and as a result of high temperature processing. A planar material has a surface that does not vary by more than ±3 mm. The thickness of each of the individual first dielectric 150 and each of the second dielectrics 160 independently can vary by no more than 5 mm, 4 mm, 3 mm, 2 mm, 1 mm or 0.5 mm relative to the average thickness of the component.

Referring to expanded view of FIG. 4, the total thickness Tₜ of the first dielectric 150 and the second dielectric 160 can impact the plasma formed in the process region 195 adjacent the bottom 112 of the housing 110 and the outer face 162 of the second dielectric 160. The total thickness Tₜ is the sum of the first thickness T₁ and the second thicknesses T₂ of each of the second dielectric 160. In some embodiments, the sum of the first thickness T₁ and the second thicknesses T₂ of each of the second dielectrics 160 is in the range of about 10 mm to about 17 mm, or in the range of about 12 mm to about 16 mm, or in the range of about 13 mm to about 15 mm. In some embodiments, the total thickness Tₜ is less than or equal to about 16 mm, 15 mm, 14 mm, 13 mm or 12 mm. In some embodiments, the sum of the thickness of the first dielectric T₁ and each of the second dielectrics T₂ is about 15 mm.

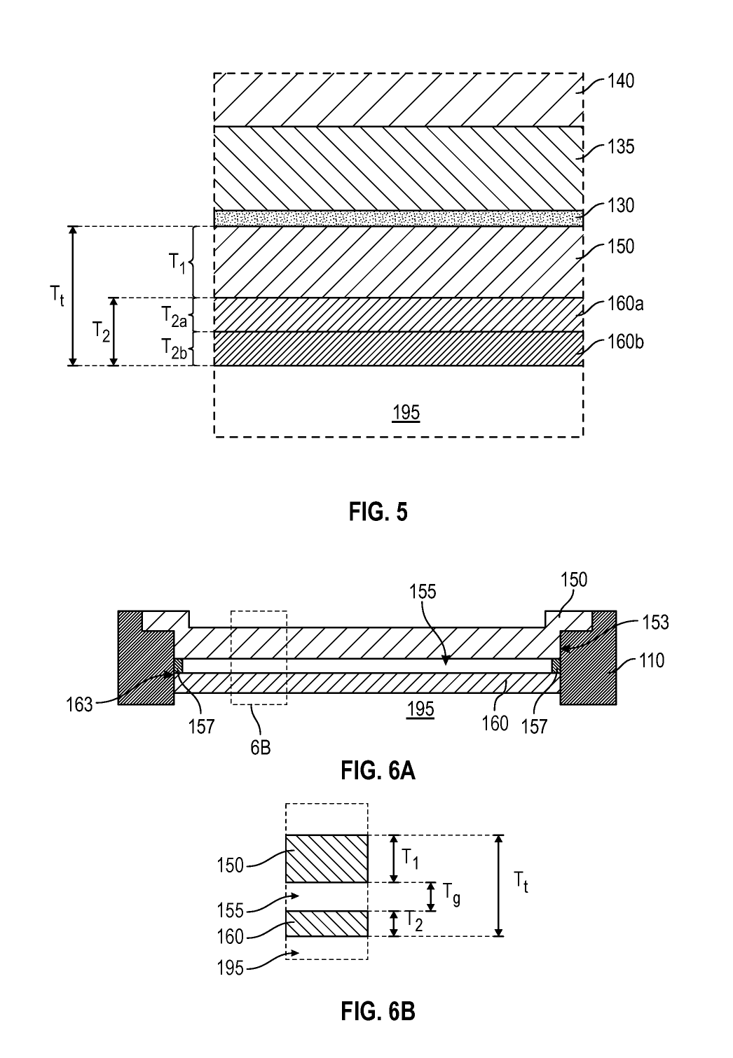

FIGS. 2-4 illustrate an embodiment of the disclosure in which there is one second dielectric 160. The term “second” used in relation to the dielectrics means a different component than the first dielectric. The first dielectric 150 is positioned adjacent the powered electrode 130, the second dielectric(s) 160 are on the opposite side of the first dielectric 150 from the powered electrode 130. In some embodiments, there can be more than one second dielectric 160. In some embodiments, there are two, three or four second dielectrics 160. FIG. 5 illustrates an embodiment in which there are two second dielectrics 160a, 160b. One second dielectric 160a is positioned adjacent the first dielectric 150 and the other second dielectric 160b is on an opposite side of the second dielectric 160a than the first dielectric 150.

The total thickness Tₜ of the combined first dielectric 150 and second dielectrics 160a, 160b, are the sum of the first thickness T₁, the second thickness T₂ₐ (of second dielectric 160a) and the second thickness T_{2b} (of second dielectric 160b). The second thickness T₂ is the sum of the second thickness T₂ₐ and the second thickness T_{2b}. In some embodiments, the first thickness T₁ is greater than the second thickness T₂. In some embodiments, the first thickness T₁ is greater than 50% of the sum of the first thickness T₁ and the second thickness T₂ of each of the second dielectrics 160. Stated differently, in some embodiments, the first dielectric 150 is thicker than 50% of the total thickness Tₜ.

Referring back to FIGS. 2 and 3, some embodiments of the plasma source assembly 100 include a high temperature O-ring 170 between the housing 110 and the first dielectric 150. While three O-rings are shown, the skilled artisan will recognize that there can be more or less than three O-rings and that the placement can be altered. The high-temperature O-ring 170 provides for a gas-tight seal between the housing 110 and the first dielectric 150. As the first dielectric 150 expands and contract with temperature changes, the O-ring 170 prevents the first dielectric 150 from breaking due to contact with the housing 110. The portion of the housing 110 above the powered electrode 130 can be at atmospheric conditions while the process region 195 can be at reduced pressure. The O-ring helps maintain and cushion the first dielectric 150 from thermal and pressure differences.

In some embodiments, the second dielectric 160 does not have an O-ring between the housing 110 and the second dielectric 160. The second dielectric 160 is on the low pressure side of the first dielectric 150 and does not experience pressure differentials like the first dielectric 150.

Referring to FIG. 6A, in some embodiments the second dielectric 160 is spaced from the first dielectric 150 to form a gap 155. As shown in FIG. 6B, which is an expanded view of region 6B in FIG. 6A, the thickness T_{g} of the gap 155 is included in the total thickness Tₜ of the dielectrics. In the illustrated embodiment, the total thickness Tₜ is equal to the sum of the first thickness T₁, the gap thickness T_{g} and the second thickness T₂. The thickness T_{g} of the gap can be any suitable thickness so that the total thickness Tₜ is not greater than 17 mm and the first thickness T₁ is greater than 50% of the total thickness Tₜ. The second dielectric 160 can be spaced from the first dielectric 150 by a dielectric shim 157 positioned around at least a portion of the outer periphery 153 of the first dielectric 150 and at least a portion of the outer periphery 163 of the second dielectric 160.

The illustrated embodiments show a wedge-shaped housing 110. In embodiments of this sort, each of the ground electrode 140, ground dielectric 135, first dielectric 150 and second dielectric(s) 160 are wedge-shaped to conform to the shape of the housing 110. In some embodiments, the housing is round and the dielectrics and ground electrode conform to the round shape of the housing.

The powered electrode can be made of any suitable material that can transmit microwave energy. In some embodiments, the powered electrode comprises one or more of tungsten (W), molybdenum (Mo) or tantalum (Ta).

The cross-sectional shape of the powered electrode 130 can be any suitable shape. For example, the powered electrode 130 can be cylindrical extending from the first end to the second end and the cross-sectional shape would be round or oval. In some embodiments, the powered electrode is a flat conductor. As used in this manner, the term “flat conductor” means a conductive material with a rectangular prism shape in which the cross-section is a rectangle. A flat conductor has a height or thickness T_{c}. The thickness T_{c} of the flat conductor can be any suitable thickness depending on, for example, the powered electrode 130 material. In some embodiments, the powered electrode 130 has a thickness in the range of about 5 μm to about 5 mm, 0.1 mm to about 5 mm, or in the range of about 0.2 mm to about 4 mm, or in the range of about 0.3 mm to about 3 mm, or in the range of about 0.5 mm to about 2.5 mm, or in the range of about 1 mm to about 2 mm. In some embodiments, the powered electrode 130 has a substantially uniform width from the first end to the second end. In some embodiments, the width of the powered electrode 130 changes from the first end to the second end.

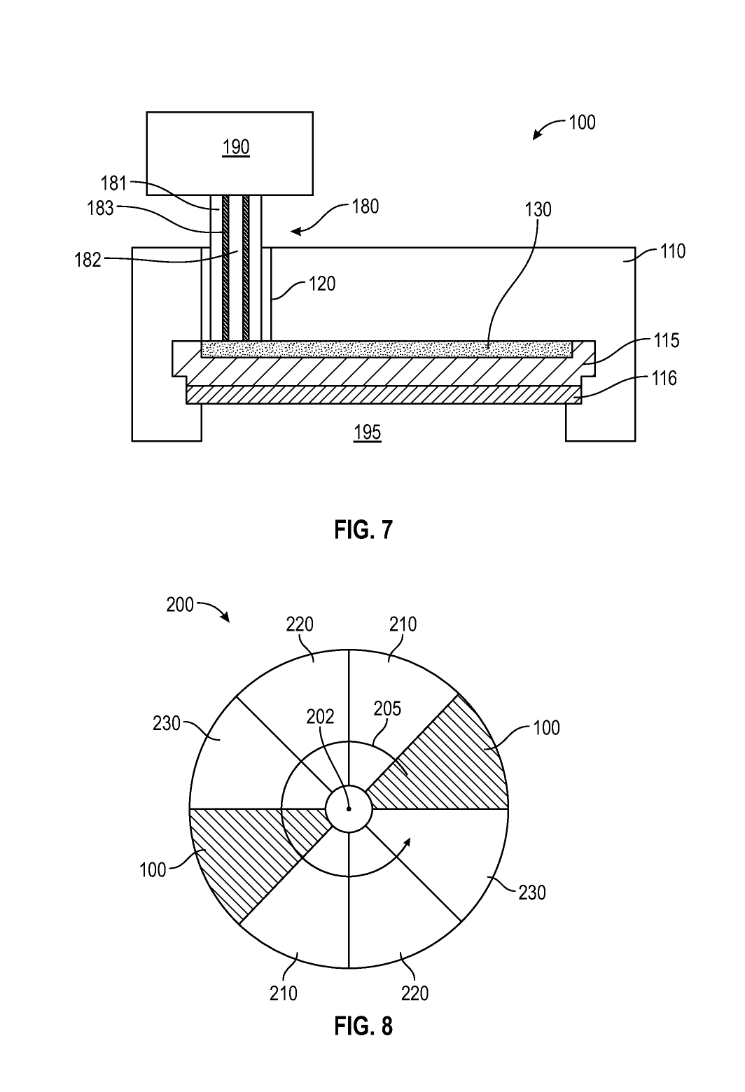

Referring to FIG. 7, some embodiments of the plasma source assembly 100 include at least one feed line 180 in electrical communication with and between a microwave generator 190 and the powered electrode 130. The feed line 180 illustrated is a coaxial feed line that includes an outer conductor 181 and inner conductor 182 arranged in a coaxial configuration. The inner conductor 181 can be in electrical communication with powered electrode 130 and the outer conductor 182 can be in electrical contact with the ground electrode 310 to form a complete electrical circuit. The inner conductor 181 and the outer conductor are separated by an insulator 183 to prevent shorting along the feed line 180.

Some embodiments include a microwave generator 190 electrically coupled to the powered electrode 130 through the feed line 180. The microwave generator 190 operates at a frequency in the range of about 300 MHz to about 300 GHz, or in the range of about 900 MHz to about 930 MHz, or in the range of about 1 GHz to about 10 GHz, or in the range of about 1.5 GHz to about 5 GHz, or in the range of about 2 GHz to about 3 GHz, or in the range of about 2.4 GHz to about 2.5 GHz, or in the range of about 2.44 GHz to about 2.47 GHz, or in the range of about 2.45 GHz to about 2.46 GHz.

Referring to FIG. 8, additional embodiments of the disclosure are directed to gas distribution assemblies 200 comprising the plasma source assembly 100. The gas distribution assembly 200 illustrated is made up of eight segments or sectors. Each segment or sector can be a separate component that can be assembled to form the circular gas distribution assembly. In the embodiment shown, two plasma source assemblies 100 are positioned on opposite sides of the circular gas distribution assembly with a first injector unit 210, second injector unit 220 and third injector unit 230 positioned between the opposing plasma source assemblies 100. A wafer rotated in a circular path 205 around central axis 202 would be exposed to the first injector unit 210, the second injector unit 220, the third injector unit 230 and the plasma source assembly 100 as a fourth unit in the sequence. One full rotation around the system illustrated would expose the substrate to two cycles of injector unit exposures.

While the foregoing is directed to embodiments of the present disclosure, other and further embodiments of the disclosure may be devised without departing from the basic scope thereof, and the scope thereof is determined by the claims that follow.

What is claimed is:

1. A plasma source assembly comprising:
a housing having a top, a bottom and at least one sidewall;
a powered electrode within the housing and having a first end and a second end defining a length;
a ground electrode on a first side of the powered electrode within the housing, the ground electrode spaced from the powered electrode by a distance;
a first dielectric within the housing on a second side of the powered electrode, the first dielectric and ground electrode enclosing the powered electrode, the first dielectric having an inner face adjacent the powered electrode and an outer face opposite the inner face, inner face and outer face defining a first thickness; and
at least one second dielectric adjacent to the outer face of the first dielectric, each of the second dielectrics having an inner face and an outer face defining a second thickness,
wherein the sum of the first thickness and the second thickness of each of the second dielectrics is in the range of about 10 mm to about 17 mm.

2. The plasma source assembly of claim 1, wherein each of the first dielectric and the at least one second dielectric are substantially planar.

3. The plasma source assembly of claim 1, wherein the sum of the first thickness and the second thickness of each of the second dielectrics is in the range of about 13 mm to about 15 mm.

4. The plasma source assembly of claim 3, wherein the sum of the thicknesses is about 15 mm.

5. The plasma source assembly of claim 1, wherein the first thickness is greater than the second thickness.

6. The plasma source assembly of claim 1, wherein the first thickness is greater than 50% of the sum of the first thickness and the second thickness of each of the second dielectrics.

7. The plasma source assembly of claim 1, further comprising a high temperature O-ring between the housing and the first dielectric.

8. The plasma source assembly of claim 1, wherein the housing is wedge-shaped with an inner peripheral end and an outer peripheral end defining a length of the housing, a first side and a second side defining the width of the housing, the width varying from smaller at the inner peripheral end that at the outer peripheral end.

9. The plasma source assembly of claim 8, wherein each of the ground electrode, first dielectric and at least one second dielectric are wedge-shaped to conform to the housing.

10. The plasma source assembly of claim 1, wherein the powered electrode is a flat conductor.

11. The plasma source assembly of claim 1, wherein there are two second dielectrics with one second dielectric adjacent the first dielectric and the other second dielectric on the opposite side of the one second dielectric from the first dielectric, the combined thickness of the first dielectric and second dielectrics is about 13 to about 15 mm.

12. The plasma source assembly of claim 11, wherein the first dielectric is thicker than 50% of the total thickness of the first dielectric and the second dielectrics.

13. The plasma source assembly of claim 1, wherein the second dielectric is spaced from the first dielectric to form a gap, the gap included in the total thickness.

14. The plasma source assembly of claim 13, wherein the gap is formed by a dielectric shim around an outer periphery of the first dielectric and the second dielectric.

15. The plasma source assembly of claim 1, wherein each of the first dielectric and the at least one second dielectric are independently selected from the group consisting of quartz, ceramic and hybrid materials.

16. The plasma source assembly of claim 1, wherein the powered electrode comprises one or more of tungsten (W), molybdenum (Mo) or tantalum (Ta).

17. The plasma source assembly of claim 1, further comprising at least one feed line in electrical communication with and between a microwave generator and the powered electrode.

18. A gas distribution assembly comprising the plasma source assembly of claim 1.

19. The gas distribution assembly of claim 18, wherein the plasma source assembly is a wedge-shaped component and additional wedge-shaped injector units are arranged to form a circular gas distribution assembly.

20. A method of providing a plasma, the method comprising:
providing microwave power from a microwave generator to a powered electrode, the powered electrode enclosed in a dielectric with a ground electrode on a first side of the powered electrode, a first dielectric on a second side of the powered electrode and at least one second dielectric on an opposite side of the first dielectric from the powered electrode, wherein a plasma is formed adjacent the second dielectric on a second side of the second dielectric opposite the first dielectric, wherein the sum of the thickness of the first dielectric and the at least one second dielectric is in the range of about 10 mm to about 17 mm.
